(19) United States
(12) Patent Application Publication
(10) Pub. No.: US 2023/0207285 A1
(43) Pub. Date: Jun. 29, 2023

(54) PLASMA PROCESSING APPARATUS AND ELECTROSTATIC CHUCK MANUFACTURING METHOD

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 18/088,870

(22) Filed: Dec. 27, 2022

(30) Foreign Application Priority Data
Dec. 27, 2021 (JP) 2021-213275
Nov. 30, 2022 (JP) 2022-191180

(51) Int. Cl. H01J 37/32

(52) U.S. Cl. CPC H01J 37/32715; H01J 37/32091; H01J 2237/2007

(57) ABSTRACT

There is provided a plasma processing apparatus including: a plasma processing chamber; a substrate support disposed in the plasma processing chamber, the substrate support including: a dielectric member having a substrate supporting surface; a first filter element disposed in the dielectric member, the first filter element having a first terminal and a second terminal; and a first electrode disposed in the dielectric member, the first electrode being electrically connected to the first terminal. The plasma processing apparatus includes an RF generator coupled to the plasma processing chamber and configured to generate an RF signal; and a first DC generator electrically connected to the second terminal and configured to generate a DC signal.

### CROSS-REFERENCE TO RELATED APPLICATIONS

This application claims priority to Japanese Patent Application Nos. 2021-213275 filed on Dec. 27, 2021 and 2022-191180 filed on Nov. 30, 2022, respectively, the entire contents of which are incorporated herein by reference.

### TECHNICAL FIELD

The present disclosure relates to a plasma processing apparatus and an electrostatic chuck manufacturing method.

### BACKGROUND

As a plasma processing apparatus including an electrostatic chuck, there is a technique disclosed in U.S. Patent Application Publication No. 2020/0343123.

### SUMMARY

The present disclosure provides a technique capable of reducing loss or leakage of an RF power.

In accordance with an aspect of the present disclosure, there is provided a plasma processing apparatus comprising: a plasma processing chamber; a substrate support disposed in the plasma processing chamber, the substrate support including: a dielectric member having a substrate supporting surface; a first filter element disposed in the dielectric member, the first filter element having a first terminal and a second terminal; and a first electrode disposed in the dielectric member, the first electrode being electrically connected to the first terminal; an RF generator coupled to the plasma processing chamber and configured to generate an RF signal; and a first DC generator electrically connected to the second terminal and configured to generate a DC signal.

### BRIEF DESCRIPTION OF THE DRAWINGS

The objects and features of the present disclosure will become apparent from the following description of embodiments, given in conjunction with the accompanying drawings, in which:

FIG. 1 explains a configuration example of a plasma processing system;

FIG. 2 explains a configuration example of a capacitively coupled plasma processing apparatus;

FIG. 3 shows a configuration example of a substrate support 11;

FIG. 4 shows a configuration example of a filter element 52;

FIG. 5 shows another configuration example of the filter element 52;

FIG. 6 shows still another configuration example of the filter element 52;

FIG. 7 is a flowchart showing an example of a method of manufacturing filter elements 52 and 62;

FIGS. 8A to 8H show an example of a method of manufacturing the filter elements 52 and 62;

FIG. 9 shows another configuration example of the substrate support 11; and

FIG. 10 shows still another configuration example of the substrate support 11.

### DETAILED DESCRIPTION

Hereinafter, embodiments of the present disclosure will be described below.

In accordance with one exemplary embodiment, there is provided a plasma processing apparatus. The plasma processing apparatus comprising: a plasma processing chamber; a substrate support disposed in the plasma processing chamber, the substrate support including: a dielectric member having a substrate supporting surface; a first filter element disposed in the dielectric member, the first filter element having a first terminal and a second terminal; and a first electrode disposed in the dielectric member, the first electrode being electrically connected to the first terminal; an RF generator coupled to the plasma processing chamber and configured to generate an RF signal; and a first DC generator electrically connected to the second terminal and configured to generate a DC signal.

In accordance with one exemplary embodiment, the first electrode includes an electrostatic chuck electrode.

In accordance with one exemplary embodiment, the first electrode includes a bias electrode.

In accordance with one exemplary embodiment, the first filter element is a low pass filter.

In accordance with one exemplary embodiment, the first filter element includes a first resistance element.

In accordance with one exemplary embodiment, the first resistance element is disposed to be perpendicular to the substrate supporting surface.

In accordance with one exemplary embodiment, the first resistance element is disposed to be parallel to the substrate supporting surface.

In accordance with one exemplary embodiment, the first electrode is disposed to be parallel to the substrate supporting surface, the first resistance element is disposed below the first electrode to be parallel to the first electrode, and the first resistance element has the first terminal and the second terminal.

In accordance with one exemplary embodiment, the first resistance element has a plurality of resistance wirings electrically connected each other in parallel between the first terminal and the second terminal.

In accordance with one exemplary embodiment, the first resistance element has a curved/bent line pattern in a plan view of the substrate supporting surface.

In accordance with one exemplary embodiment, the first filter element includes a second resistance element, the second resistance element is disposed below the first resistance element to be parallel to the first resistance element, the second resistance element has a third terminal and a fourth terminal, the third terminal is electrically connected to the first electrode through the second terminal, and the fourth terminal is electrically connected to the first DC generator.

In accordance with one exemplary embodiment, the first filter element includes a first inductor element.

In accordance with one exemplary embodiment, the first inductor element is disposed to be parallel to the substrate supporting surface.

In accordance with one exemplary embodiment, the first electrode is disposed to be parallel to the substrate supporting surface, the first inductor element is disposed below the first electrode to be parallel to the first electrode, and the first inductor element has the first terminal and the second terminal.

In accordance with one exemplary embodiment, the first inductor element has a spiral line pattern in a plan view of the substrate supporting surface.

In accordance with one exemplary embodiment, the first filter element includes a second inductor element, the second inductor element is disposed below the first inductor element to be parallel to the first inductor element, the second inductor element has a third terminal and a fourth terminal, the third terminal is electrically connected to the first electrode through the second terminal, and the fourth terminal is electrically connected to the first DC generator.

In accordance with one exemplary embodiment, the plasma processing apparatus further comprises a second DC generator configured to generate a DC signal. The dielectric member has a ring supporting surface around the substrate supporting surface, the substrate support includes: a second filter element disposed in the dielectric member and having a fifth terminal and a sixth terminal; and a second electrode disposed in the dielectric member and electrically connected to the fifth terminal, and the second DC generator is electrically connected to the sixth terminal.

In accordance with one exemplary embodiment, the plasma processing apparatus further comprises an RF electrode electrically connected to the RF generator. The RF electrode includes a metal member, and the metal member is bonded to the dielectric member.

In accordance with one exemplary embodiment, the plasma processing apparatus further comprises an RF electrode electrically connected the RF generator, and the RF electrode is disposed in the dielectric member.

In accordance with one exemplary embodiment, there is provided an electrode chuck manufacturing method. The electrode chuck manufacturing method comprising: preparing a first dielectric layer having a first surface and a second surface opposite to the first surface; forming an electrode on the first surface; forming a plug in the first dielectric layer to penetrate therethrough, one end of the plug being connected to the electrode on the first surface and the other end of the plug being exposed on the second surface; preparing a second dielectric layer having a third surface and a fourth surface opposite to the third surface; forming a filter element on the third surface; and connecting a part of the filter element and the other end of the plug by bonding the second surface of the first dielectric layer and the third surface of the second dielectric layer.

Hereinafter, embodiments of the present disclosure will be described in detail with reference to the accompanying drawings. Like reference numerals will be given to like or corresponding parts throughout the drawings, and redundant description thereof will be omitted. Unless otherwise specified, positional relationships such as up, down, left, and right are based on the positional relationships shown in the drawings. The dimensional ratios in the drawings do not indicate the actual ratios, and the actual ratios are not limited to the illustrated ratios.

<Example of Plasma Processing System>

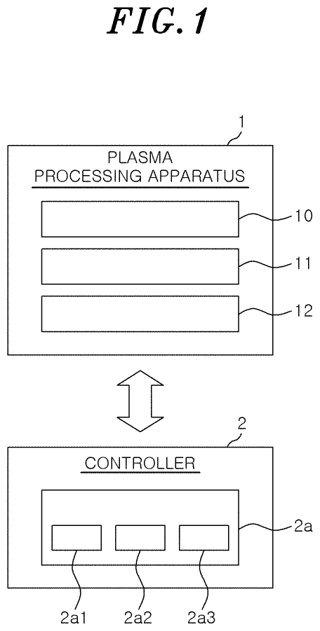

FIG. 1 explains a configuration example of a plasma processing system. In one embodiment, a plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port for supplying at least one processing gas to the plasma processing space and at least one gas exhaust port for exhausting a gas from the plasma processing space. The gas supply port is connected to a gas supply 20 to be described later, and the gas exhaust port is connected to an exhaust system 40 to be described later. The substrate support 11 is disposed in the plasma processing space and has a substrate supporting surface for supporting the substrate.

The plasma generator 12 is configured to generate a plasma from at least one processing gas supplied into the plasma processing space. The plasma generated in the plasma processing space includes a capacitively coupled plasma (CCP), an inductively coupled plasma (ICP), an electron-cyclotron-resonance plasma (ECR), a helicon wave excited plasma (HWP), a surface wave plasma (SWP), or the like. Further, various types of plasma generators such as an alternating current (AC) plasma generator and a direct current (DC) plasma generator may be used. In one embodiment, an AC signal (AC power) used in the AC plasma generator has a frequency within a range of 100 kHz to 10 GHz. Therefore, the AC signal includes a radio frequency (RF) signal and a microwave signal. In one embodiment, the RF signal has a frequency within a range of 100 kHz to 150 MHz.

<Example of CCP Plasma Processing Apparatus>

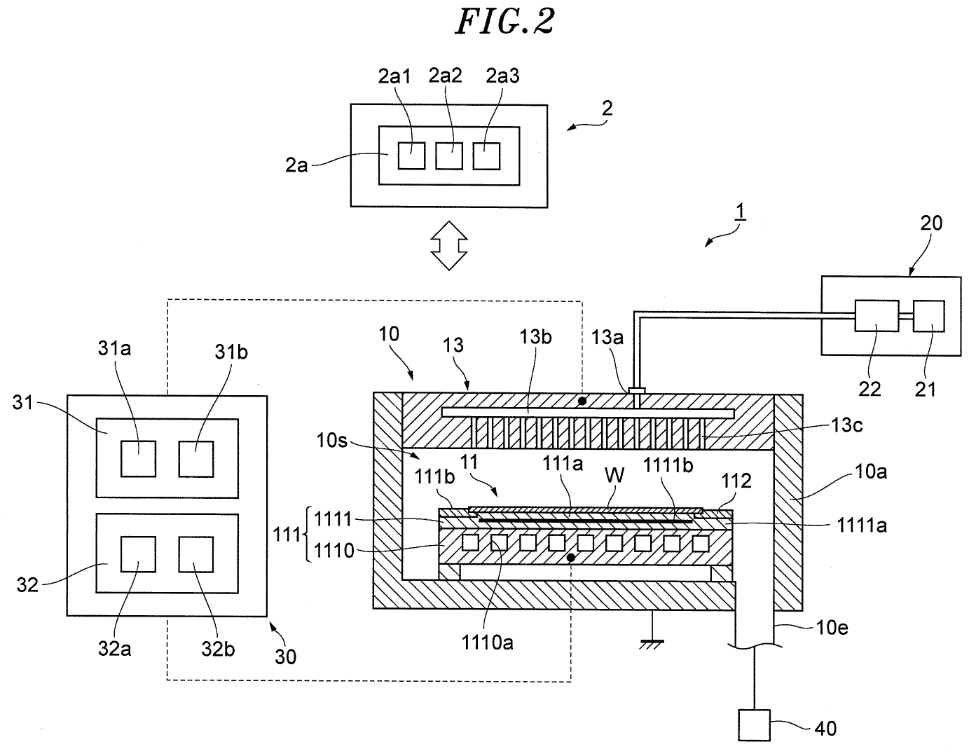

FIG. 2 explains a configuration example of a capacitively coupled plasma processing apparatus.

The plasma processing system includes the capacitively coupled plasma processing apparatus 1 and the controller 2. The capacitively coupled plasma processing apparatus 1 includes the plasma processing chamber 10, the gas supply 20, a power supply 30, and the exhaust system 40. The plasma processing apparatus 1 further includes the substrate support 11 and a gas introducing unit. The gas introducing unit is configured to introduce at least one processing gas into the plasma processing chamber 10. The gas introducing unit includes a showerhead 13. The substrate support 11 is disposed in the plasma processing chamber 10. The showerhead 13 is disposed above the substrate support 11. In one embodiment, the showerhead 13 forms at least a part of the ceiling of the plasma processing chamber 10. The plasma processing chamber 10 has a plasma processing space 10s defined by the showerhead 13, a sidewall 10a of the plasma processing chamber 10, and the substrate support 11. The plasma processing chamber 10 has at least one gas supply port for supplying at least one processing gas to the plasma processing space 10s and at least one gas exhaust port for exhausting a gas from the plasma processing space. The plasma processing chamber 10 is grounded. The showerhead 13 and the substrate support 11 are electrically insulated from the housing of the plasma processing chamber 10.

The substrate support 11 includes a main body 111 and a ring assembly 112. The main body 111 has a central region 111a for supporting the substrate W and an annular region 111b for supporting the ring assembly 112. A wafer is an example of a substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 to surround the substrate W on the central region 111a of the main body 111. Hence, the central region 111a is also referred to as “substrate supporting surface” for supporting the substrate W, and the annular region 111b is also referred to as “ring supporting surface” for supporting the ring assembly 112.

In one embodiment, the main body 111 includes a base 1110 and an electrostatic chuck 1111. The base 1110 includes a conductive member. The conductive member of the base 1110 can function as a lower electrode. The electrostatic chuck 1111 is disposed on the base 1110. The electrostatic chuck 1111 includes a ceramic member 1111a and an electrode 1111b disposed in the ceramic member 1111a. In one embodiment, the electrode 1111b includes an electrostatic chuck electrode. The ceramic member 1111a has the central region 111a. In one embodiment, the ceramic member 1111a also has the annular region 111b. Another member surrounding the electrostatic chuck 1111, such as an annular electrostatic chuck or an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, at least one radio frequency (RF)/direct current (DC) electrode coupled to an RF power supply 31 and/or a DC power supply 32, which will be described later, may be disposed in the ceramic member 1111a. In this case, at least one RF/DC electrode functions as the lower electrode. If a bias RF signal and/or a DC signal, which will be described later, is supplied to at least one RF/DC electrode, the RF/DC electrode is also referred to as “bias electrode.” The conductive member of the base 1110 and at least one RF/DC electrode may function as a plurality of lower electrodes. Alternatively, the electrode 1111b may function as the lower electrode. In this case, the electrode 1111b includes the bias electrode. Accordingly, the substrate support 11 includes at least one lower electrode.

The ring assembly 112 includes one or more annular members. In one embodiment, one or more annular members include one or more edge rings and at least one cover ring. The edge ring is made of a conductive material or an insulating material, and the cover ring is made of an insulating material.

Further, the substrate support 11 may include a temperature control module configured to control at least one of the electrostatic chuck 1111, the ring assembly 112, and the substrate to a target temperature. The temperature control module may include a heater, a heat transfer medium, channels 1110a, or a combination thereof. A heat transfer fluid, such as brine or a gas, flows through the channels 1110a. In one embodiment, the channels 1110a are formed in the base 1110, and one or more heaters are disposed in the ceramic member 1111a of the electrostatic chuck 1111. The substrate support 11 may include a heat transfer gas supply configured to supply a heat transfer gas to the gap between the backside of the substrate W and the central region 111a.

The showerhead 13 is configured to introduce at least one processing gas from the gas supply 20 into the plasma processing space 10s. The showerhead 13 has at least one gas supply port 13a, at least one gas diffusion space 13b, and a plurality of gas introducing ports 13c. The processing gas supplied to the gas supply port 13a passes through the gas diffusion space 13b and is introduced into the plasma processing space 10s through the gas introducing ports 13c. The showerhead 13 includes at least one upper electrode. The gas introducing unit may include, in addition to the showerhead 13, one or more side gas injectors (SGI) attached to one or more openings formed in the sidewall 10a.

The gas supply 20 may include at least one gas source 21 and at least one flow controller 22. In one embodiment, the gas supply 20 is configured to supply at least one processing gas from the corresponding gas source 21 through the corresponding flow controller 22 to the showerhead 13. The flow controllers 22 may include, e.g., a mass flow controller or a pressure-controlled flow controller. The gas supply 20 may include one or more flow modulation devices for modulating the flow rate of at least one processing gas or causing it to pulsate.

The power supply 30 includes an RF power supply 31 coupled to the plasma processing chamber 10 through at least one impedance matching circuit. The RF power supply 31 is configured to supply at least one RF signal (RF power) to at least one lower electrode and/or at least one upper electrode. Accordingly, plasma is generated from at least one processing gas supplied to the plasma processing space 10s. Therefore, the RF power supply 31 may function as at least a part of a plasma generator configured to generate a plasma from one or more processing gases in the plasma processing chamber 10. Further, by supplying the bias RF signal to at least one lower electrode, a bias potential is generated at the substrate W, and ions in the generated plasma can be attracted to the substrate W.

In one embodiment, the RF power supply 31 includes a first RF generator 31a and a second RF generator 31b. The first RF generator 31a is coupled to at least one lower electrode and/or at least one upper electrode through at least one impedance matching circuit, and is configured to generate a source RF signal (source RF power) for plasma generation. In one embodiment, the source RF signal has a frequency within a range of 10 MHz to 150 MHz. In one embodiment, the first RF generator 31a may be configured to generate a plurality of source RF signals having different frequencies. The generated one or more source RF signals are supplied to at least one lower electrode and/or at least one upper electrode.

The second RF generator 31b is coupled to the at least one lower electrode through at least one impedance matching circuit, and is configured to generate a bias RF signal (bias RF power). The frequency of the bias RF signal may be the same as or different from the frequency of the source RF signal. In one embodiment, the bias RF signal has a frequency lower than the frequency of the source RF signal. In one embodiment, the bias RF signal has a frequency within a range of 100 kHz to 60 MHz. In one embodiment, the second RF generator 31b may be configured to generate multiple bias RF signals having different frequencies. The generated one or more bias RF signals are supplied to at least one lower electrode. In various embodiments, at least one of the source RF signal and the bias RF signal may pulsate.

The power supply 30 may include a DC power supply 32 coupled to the plasma processing chamber 10. The DC power supply 32 includes a first DC generator 32a and a second DC generator 32b. In one embodiment, the first DC generator 32a is connected to the at least one lower electrode, and is configured to generate a first DC signal. The generated first DC signal is applied to at least one lower electrode. In one embodiment, the second DC generator 32b is connected to at least one upper electrode, and is configured to generate a second DC signal. The generated second DC signal is applied to at least one upper electrode.

In various embodiments, at least one of the first DC signal and the second DC signal may pulsate. In this case, a sequence of voltage pulses is applied to at least one lower electrode and/or at least one upper electrode. The waveform of the voltage pulses may have a rectangular shape, a trapezoidal shape, a triangular shape, or a combination thereof. In one embodiment, a waveform generator for generating a sequence of voltage pulses from a DC signal is connected between the first DC generator 32a and at least one lower electrode. Therefore, the first DC generator 32a and the waveform generator constitute a voltage pulse generator. When the second DC generator 32b and the waveform generator constitute a voltage pulse generator, the voltage pulse generator is connected to at least one upper electrode. The voltage pulse may have positive polarity or negative polarity. Further, the sequence of voltage pulses may include one or more positive voltage pulses and one or more negative voltage pulses in one cycle. The first and second DC generators 32a and 32b may be provided in addition to the RF power supply 31, and the first DC generator 32a may be provided instead of the second RF generator 31b.

The exhaust system 40 may be connected to a gas exhaust port 10e disposed at the bottom portion of the plasma processing chamber 10, for example. The exhaust system 40 may include a pressure control valve and a vacuum pump. The pressure control valve adjusts a pressure in the plasma processing space 10s. The vacuum pump may include a turbo molecular pump, a dry pump, or a combination thereof.

<Configuration Example of Substrate Support 11>

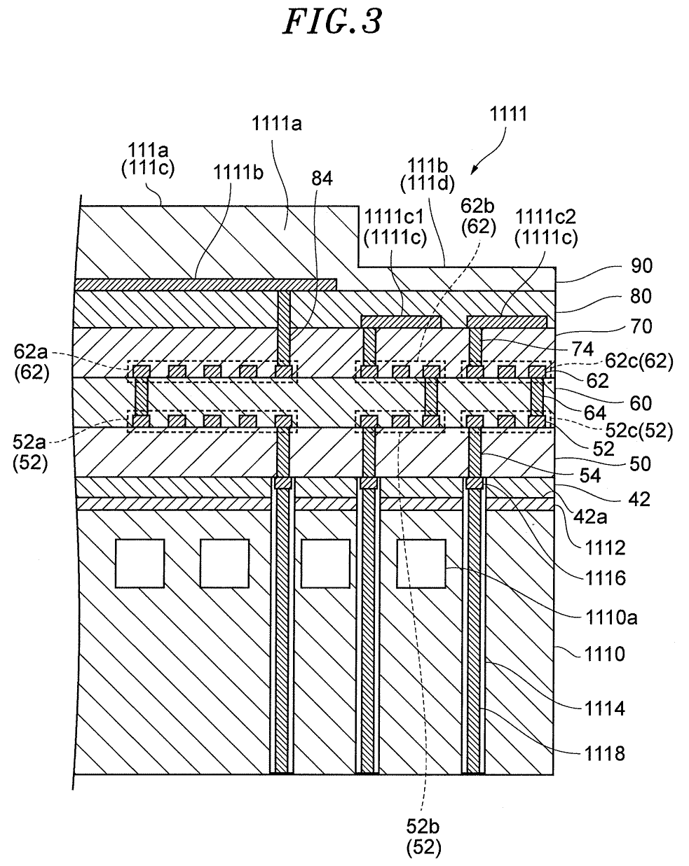

FIG. 3 shows a configuration example of the substrate support 11 shown in FIG. 2. FIG. 3 shows a cross section of a part of the substrate support 11. In the configuration example shown in FIG. 3, the substrate support 11 includes the base 1110, the electrostatic chuck 1111, and a bonding member 1112. The base 1110 is bonded to the electrostatic chuck 1111 via the bonding member 1112. The bonding member 1112 may be, e.g., a silicon-containing adhesive. The electrostatic chuck 1111 has a bonding surface 42a for bonding with the bonding member 1112 or the base 1110.

One or more through-holes 1114 are formed in the base 1110. Each through-hole 1114 may extend from the base 1110 to the bonding member 1112 and a part of the ceramic member 1111a. For example, each through-hole 1114 is formed through the bonding member 1112 and a dielectric layer 42. A power supply line 1118 is disposed in each through-hole 1114. One end of each power supply line 1118 is electrically connected to the electrode 1111b or 1111c through an electrode 1116 disposed at the end portion of the corresponding through-hole 1114. Further, the other end of each power supply line 1118 is electrically connected to the DC power supply 32. Each power supply line 1118 is electrically isolated from the base 1110.

In the electrostatic chuck 1111, the ceramic member 1111a includes a plurality of dielectric layers 42, 50, 60, 70, 80, and 90 (hereinafter, some or all of the dielectric layers 42, 50, 60, 70, 80 and 90 may be collectively referred to as “dielectric layer”). The ceramic member 1111a is an example of a dielectric member.

In FIG. 3, lines indicating boundaries between adjacent dielectric layers are illustrated for convenience of explanation. In other words, in FIG. 3, each dielectric layer may represent a region in the ceramic member 1111a. For example, physical boundaries may or may not exist between adjacent dielectric layers. Further, adjacent dielectric layers may contain the same dielectric material, or may contain different dielectric materials.

The ceramic member 1111a has the central region 111a for supporting the substrate W and the annular region 111b for supporting the ring assembly 112. The central region 111a has a substrate supporting surface 111c for supporting the substrate W thereon. The annular region 111b has a ring supporting surface 111d for supporting the ring assembly 112. The substrate supporting surface 111c and the ring supporting surface 111d may be disposed on the side of the ceramic member 1111a that is opposite to the bonding surface 42a side.

The electrostatic chuck 1111 has the electrode 1111b and the electrode 1111c. In one embodiment, the electrode 1111b and/or the electrode 1111c includes an electrostatic chuck electrode. Further, the electrode 1111b and/or the electrode 1111c may include a bias electrode. Hereinafter, a case in which the electrode 1111b and/or the electrode 1111c includes an electrostatic chuck electrode will be described as an example. Therefore, in the following example, the electrode 1111b and the electrode 1111c may be referred to as “electrostatic electrode 1111b” and “electrostatic electrode 1111c”, respectively. The electrostatic electrode 1111b may be an electrode for attracting the substrate W to the substrate supporting surface 111c. Further, the electrostatic electrode 1111c may be an electrode for attracting the ring assembly 112 to the ring supporting surface 111d. The electrostatic electrodes 1111b and 1111c are electrically connected to the DC power supply 32. The DC power supply 32 may apply different voltages to the electrostatic electrodes 1111b and 1111c. Further, the DC power supply 32 may apply voltages to the electrostatic electrodes 1111b and 1111c at different timings.

The electrostatic electrode 1111b may be disposed on the dielectric layer 80 in the ceramic member 1111a. Further, the electrostatic electrode 1111b may be disposed between the substrate supporting surface 111c and the bonding surface 42a. The electrostatic electrode 1111b may be disposed to be parallel to the substrate supporting surface 111c. The electrostatic electrode 1111c may be disposed on the dielectric layer 70 in the ceramic member 1111a. The electrostatic electrode 1111c may be disposed between the ring supporting surface 111d and the bonding surface 42a. The electrostatic electrode 1111c may be disposed to be parallel to the ring supporting surface 111d. The electrostatic electrode 1111c may include an electrostatic electrode 1111c1 and an electrostatic electrode 1111c2. The electrostatic electrode 1111c1 and the electrostatic electrode 1111c2 may constitute a bipolar electrostatic chuck.

The electrostatic chuck 1111 has filter elements 52 and 62. The filter elements 52 attenuate RF components contained in an RF signal passing through the filter elements 52. The filter elements 62 attenuate RF components contained in an RF signal passing through the filter elements 62. For example, the corresponding RF signal may be generated in a conductive member electrically connected to the electrostatic electrode 1111b or 1111c due to the influence of the source RF signal and/or the bias RF signal supplied to the base 1110. The conductive member is the power supply line 1118, for example. The filter elements 52 and 62 connected to the electrostatic electrode 1111b are examples of a first filter element. The filter elements 52 and 62 connected to the electrostatic electrode 1111c are examples of a second filter element.

The filter elements 52 may include filter elements 52a, 52b, and 52c (the filter elements 52a, 52b and/or 52c may also be referred to as “filter elements 52”). The filter elements 52a are electrically connected to the electrostatic electrode 1111b. The filter elements 52b are electrically connected to the electrostatic electrode 1111c1. The filter elements 52c are electrically connected to the electrostatic electrode 1111c2.

The filter elements 52 may be disposed on the dielectric layer 50. The filter elements 52 may be disposed between the electrostatic electrode 1111b and/or the electrostatic electrode 1111c and the bonding surface 42a. The filter elements 52a electrically connected to the electrostatic electrode 1111b may be disposed on the same layer as the filter elements 52b and 52c electrically connected to the electrostatic electrode 1111c. The same layer is the dielectric layer 50, for example. Plugs 54 are disposed in the dielectric layer 50 to penetrate therethrough in a direction perpendicular to the substrate supporting surface 111c. One ends of the plugs 54 are connected to the filter elements 52 (52a, 52b and 52c). The other ends of the plugs 54 is connected to the electrode 1116. The plugs 54 may function as a part of a conductive line that applies a DC signal/DC voltage generated by the DC power supply 32 to the electrostatic electrode 1111b or 1111c.

The filter elements 62 may include filter elements 62a, 62b, and 62c (the filter elements 62a, 62b and/or 62c may also be referred to as “filter elements 62”). The filter elements 62a are electrically connected to the electrostatic electrode 1111b. The filter elements 62b are electrically connected to the electrostatic electrode 1111c1. The filter elements 62c are electrically connected to the electrostatic electrode 1111c2.

The filter elements 62 may be disposed on the dielectric layer 60. The filter elements 62 may be disposed between the electrostatic electrode 1111b and/or the electrostatic electrode 1111c and the filter elements 52. The filter elements 62a electrically connected to the electrostatic electrode 1111b may be disposed on the same layer as the filter elements 62b and 62c electrically connected to the electrostatic electrode 1111c. The same layer is the dielectric layer 60, for example. Plugs 64 are disposed in the dielectric layer 60 to penetrate therethrough in a direction perpendicular to the substrate supporting surface 111c. One ends of the plugs 64 are connected to the filter elements 62 (62a, 62b and 62c). The other ends of the plugs 54 are connected to the filter elements 52 (52a, 52b and 52c). The plugs 64 may function as a part of a conductive line that applies a DC signal/DC voltage generated by the DC power supply 32 to the electrostatic electrode 1111b or 1111c.

The filter elements 62a electrically connected to the electrostatic electrode 1111b may be disposed on the same layer as the electrostatic electrode 1111c. In other words, the filter elements 62a electrically connected to the electrostatic electrode 1111b can be disposed on the dielectric layer 70. In this case, the plugs 64 connected to filter elements 52a and 62a may be disposed to penetrate through the dielectric layers 60 and 70.

The ceramic member 1111a has plugs 74 and 84. The plugs 74 are disposed in the dielectric layer 70 to penetrate therethrough. One ends of the plugs 74 are connected to the electrostatic electrode 1111c. The other ends of the plugs 74 are connected to the filter elements 62. The plug 84 is disposed in the dielectric layers 70 and 80 to penetrate therethrough. One end of the plug 84 is connected to the electrostatic electrode 1111b. The other end of the plug 84 is connected to the filter element 62.

Similarly to the filter elements 52 or 62, the plugs 54, 64, 74 and/or 84 may function as filters for attenuating RF components contained in RF signals passing through the respective plugs. When the plugs 54, 64, 74 and/or 84 function as filters, the respective plugs may contain a resistance material, for example.

The filter elements 52 and 62 may be low pass filters. For example, the filter elements 52 and 62 may be resistance elements or inductor elements. Configuration examples of the filter elements 52 and 62 will be described with reference to FIGS. 3 and 4 to 6.

<Configuration Examples of Filter Element>

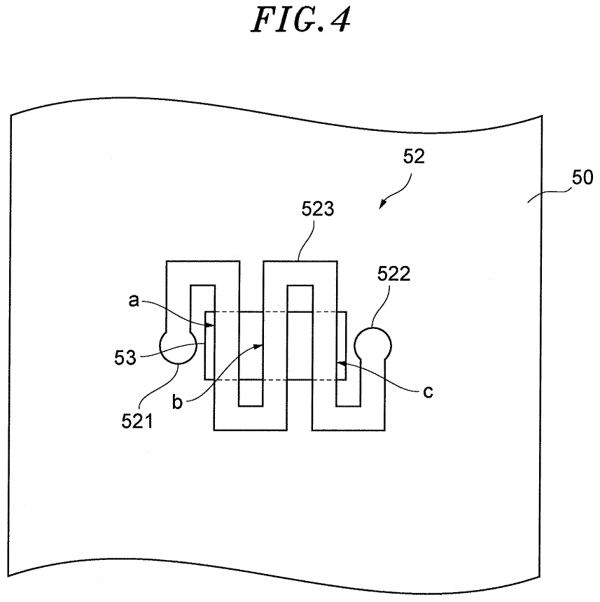

FIG. 4 shows a configuration example of the filter element 52. FIG. 4 is a plan view of the filter element 52 electrically connected to the electrostatic electrode 1111b in FIG. 3, that is, a view seen from the substrate supporting surface 111c. FIG. 4 shows, as an example, a configuration in which the filter element 52 is a resistance element. The filter element 62 may have the same configuration as that of the filter element 52 shown in FIG. 4.

The filter element 52 has terminals 521 and 522, and a resistance wiring 523. The terminals 521 and 522 and the resistance wiring 523 are disposed on the surface of the dielectric layer 50. The terminals 521 and 522 and the resistance wiring 523 may be integrally formed. Further, the terminals 521 and 522 and the resistance wiring 523 may be made of the same resistance material. The resistance material may be arbitrarily selected depending on the resistance value of the filter element 52 and/or the filter element 62. For example, the resistance value may be greater than or equal to 100 kΩ and smaller than or equal to 100 MΩ. Further, the corresponding resistance value may be greater than or equal to 1 MΩ and smaller than or equal to 10 MΩ.

Further, the resistance value of the resistance wiring 523 may be adjusted by trimming a part of the resistance wiring 523. For example, one or more parts among parts a to c of the resistance wiring 523 may be trimmed to adjust the width, thickness, area and/or volume of the resistance wiring 523, thereby adjusting the resistance value of the resistance wiring 523. For example, an opening 53 may be formed in the dielectric layer 50 to expose the parts a to c of the resistance wiring 523. A part of the resistance wiring 523 that is exposed through the opening 53 may be trimmed by laser or the like. Accordingly, a filter element having a desired resistance value or filter characteristics can be formed.

The terminal 521 is connected to one end of the resistance wiring 523. The terminal 521 is connected to the plug 64 shown in FIG. 3. The terminal 522 is connected to the other end of the resistance wiring 523. The terminal 522 is connected to the plug 54 shown in FIG. 3. The terminal 521 and/or the terminal 522 may be disposed between both ends of the resistance wiring 523 and connected to the resistance wiring 523. The terminal 521 is an example of a first terminal, a third terminal, and a fifth terminal. The terminal 522 is an example of a second terminal, a fourth terminal, and a sixth terminal.

The resistance wiring 523 may have a linear pattern in a plan view. Further, the resistance wiring 523 may have a bent line pattern as shown in FIG. 4. The pattern shape, length, area and/or volume of the resistance wiring 523 may be arbitrarily selected depending on the resistance value of the filter element 52.

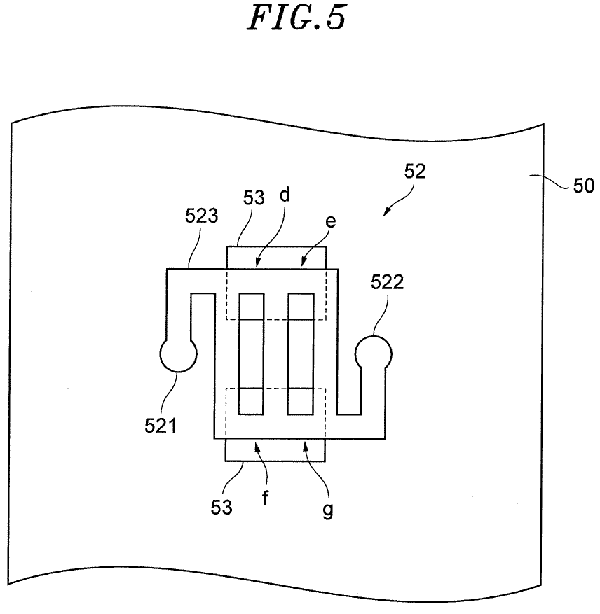

FIG. 5 shows another configuration example of the filter element 52. In the example shown in FIG. 5, the filter element 52 is a resistance element whose resistance value can be adjusted. In this example, the resistance value of the filter element 52 is adjusted by trimming a part of the filter element 52. The filter element 62 may have the same configuration as that of the filter element 52 shown in FIG. 5.

In the example shown in FIG. 5, the filter element 52 has the terminals 521 and 522, and the resistance wiring 523. The resistance wiring 523 includes a plurality of wirings electrically connected in parallel between the terminal 521 and the terminal 522. The plurality of wirings form a plurality of current paths. The resistance value of the resistance wiring 523 may be adjusted by trimming a part of the resistance wiring 523. For example, one or more parts among parts d to g of the resistance wiring 523 may be trimmed to adjust the number of wirings (current paths) included in the resistance wiring 523, or the length, area and/or volume of the resistance wiring 523, thereby adjusting the resistance value of the resistance wiring 523. For example, the opening 53 may be formed in the dielectric layer 50 to expose a part of the resistance wiring 523. A part of the resistance wiring 523 that is exposed through the opening 53 may be trimmed by laser or the like. Accordingly, a filter element having a desired resistance value or filter characteristics can be formed. The width or thickness of the resistance wiring 523 may be reduced in at least a part of the resistance wiring 523 by laser or the like.

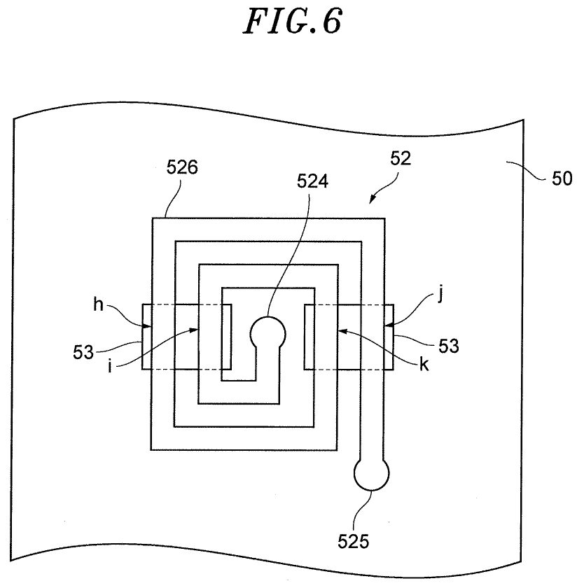

FIG. 6 shows still another configuration example of the filter element 52. FIG. 6 shows, as an example, a configuration in which the filter element 52 is an inductor element. The filter element 62 may have the same configuration as that of the filter element 52 shown in FIG. 6.

In the example shown in FIG. 6, the filter element 52 has terminals 524 and 525, and a conductive wiring 526. The terminals 524 and 525 and the conductive wiring 526 are disposed on the surface of the dielectric layer 50. The terminals 524 and 525 and the conductive wiring 526 may be integrally formed. Further, the terminals 524 and 525, and the conductive wiring 526 may be made of the same conductive material.

The terminal 524 is connected to one end of the conductive wirings 526. The terminal 524 is connected to the plug 64 shown in FIG. 3. The terminal 525 is connected to the other end of the conductive wiring 526. The terminal 525 is connected to the plug 54 shown in FIG. 3. The terminal 524 and/or the terminal 525 may be disposed between both ends of the conductive wiring 526 and connected to the conductive wiring 526. The terminal 524 is an example of the first terminal, the third terminal, and the fifth terminal. The terminal 525 is an example of the second terminal, the fourth terminal, and the sixth terminal.

The conductive wiring 526 may have a linear pattern in a plan view. Further, the conductive wiring 526 may have a spiral line pattern as shown in FIG. 6. The pattern shape, length, area and/or volume of the conductive wiring 526 may be arbitrarily selected depending on the inductance of the filter element 52.

The inductance of the filter element 52 may be adjusted by trimming a part of the conductive wire 526. For example, one or more parts among parts h to k of the conductive wire 526 may be trimmed to adjust the width, thickness, area and/or volume of conductive wiring 526, thereby adjusting the resistance of the conductive wiring 526. For example, an opening 53 may be formed in the dielectric layer 50 to expose the parts h to k of the conductive wire 526. A part of the conductive wire 526 that is exposed through the opening 53 may be trimmed by laser or the like. Accordingly, a filter element having a desired resistance value or filter characteristics can be formed. The inductance of the filter element 52 may be adjusted by adjusting the width, thickness and/or cross-sectional area of the conductive wire 526 substantially in the entire conductive wiring 526. In this case, the opening 53 may be formed to expose the entire conductive wire 526.

<Method for Manufacturing Filter Element>

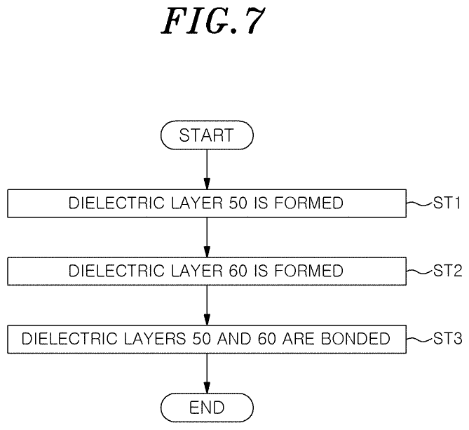

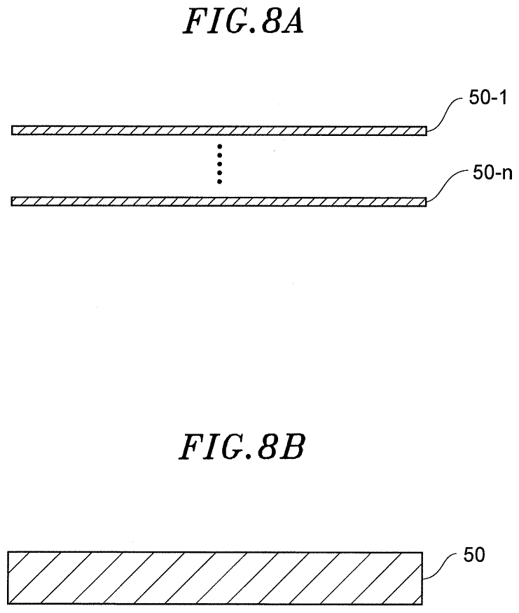

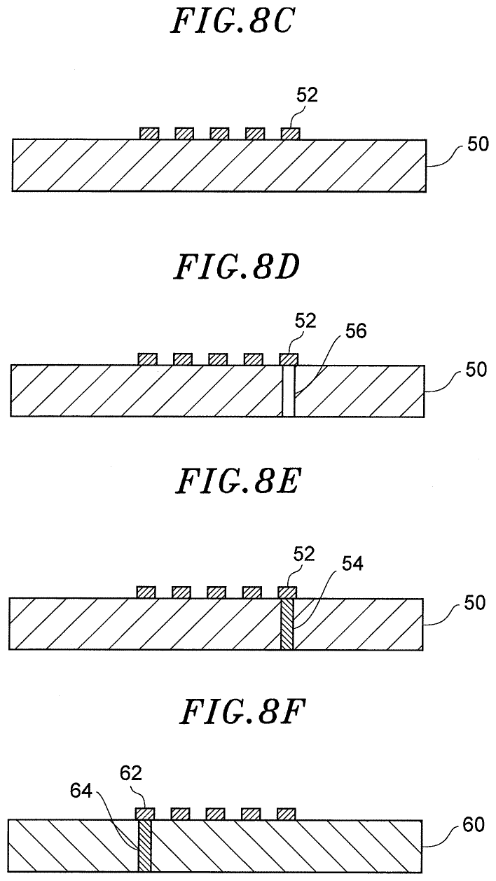

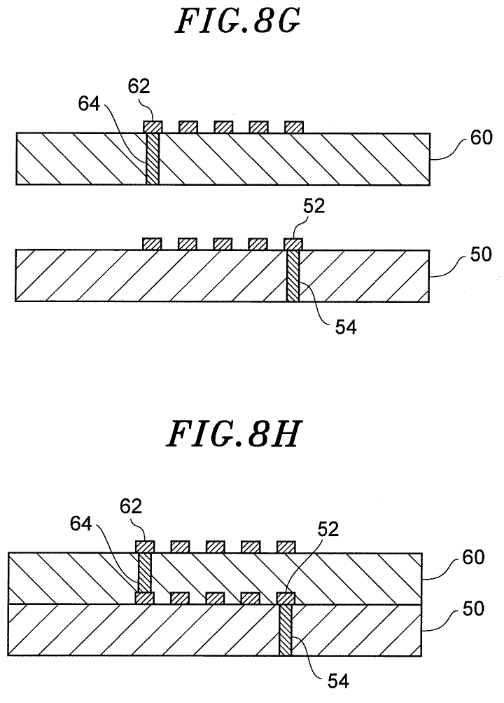

FIG. 7 is a flowchart showing an example of a method for manufacturing the filter elements 52 and 62. Such a method includes a step of forming the dielectric layer 50 (ST1), a step of forming the dielectric layer 60 (ST2), and a step of bonding the dielectric layers 50 and 60 (ST3). FIGS. 8A to 8B show examples of manufacturing processes of the filter elements 52 and 62.

First, as shown in FIG. 8A, a plurality of dielectric sheets 50-1 to 50-n are prepared (n being an integer of 2 or more). For example, the dielectric sheet may be a ceramic green sheet. The number of dielectric sheets may be arbitrarily selected depending on the thickness of the dielectric layer 50. As shown in FIG. 8B, the dielectric sheets 50-1 to 50-n are thermally compressed to form the dielectric layer 50.

Next, as shown in FIG. 8C, the filter elements 52 are formed on the surface of the dielectric layer 50. The filter elements 52 may be formed by printing or depositing a resistance material or a conductive material on the surface of the dielectric layer 50.

Next, as shown in FIG. 8D, the through-hole 56 is formed in the dielectric layer 50. The through-hole 56 is formed in the dielectric layer 50 to expose a part of the filter element 52 through the through-hole 56. The through-hole 56 may be formed to partially expose the terminals 52b and 52e shown in FIGS. 4 to 6.

Next, as shown in FIG. 8E, the plug 54 is formed in the through-hole 56. The plug 54 may be formed by filling the through-hole 56 with a resistance material or a conductive material. Accordingly, the dielectric layer 50 in which the filter elements 52 and the plugs 54 are disposed is formed (step ST1).

Next, as shown in FIG. 8F, the dielectric layer 60 in which the filter elements 62 and the plugs 64 are disposed is formed by the same steps as those shown in FIGS. 8A to 8E (step ST2).

Next, as shown in FIG. 8G, the dielectric layer 50 and the dielectric layer 60 are disposed to face each other. The dielectric layers 50 and 60 are disposed such that the surface of the dielectric layer 50 on which the filter elements 52 are formed faces the surface of the dielectric layer 60 that is opposite to the surface on which the filter elements 62 are formed.

Next, as shown in FIG. 8H, the dielectric layer 50 and the dielectric layer 60 are bonded. The dielectric layers 50 and 60 are bonded by thermocompression, for example. Accordingly, the dielectric layers 50 and 60 are bonded, and the filter elements 52 and the plug 64 are bonded, thereby electrically connecting the filter elements 52 and the filter elements 62. Hence, the dielectric layers 50 and 60 in which the filter elements 52 and 62 are disposed are formed (step ST3).

The dielectric layers 42, 70, 80 and 90 may be formed in the same manner by some or all of the steps shown in FIGS. 8A to 8H. By bonding the dielectric layers 42 to 90, the electrostatic chuck 1111 shown in FIG. 3 is formed.

<Another Configuration Example of Substrate Support 11>

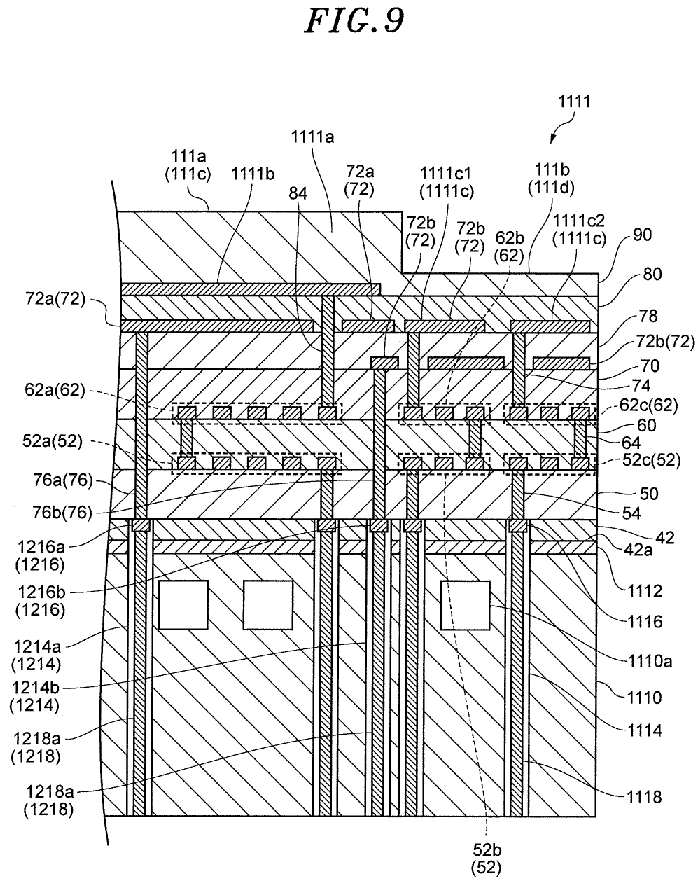

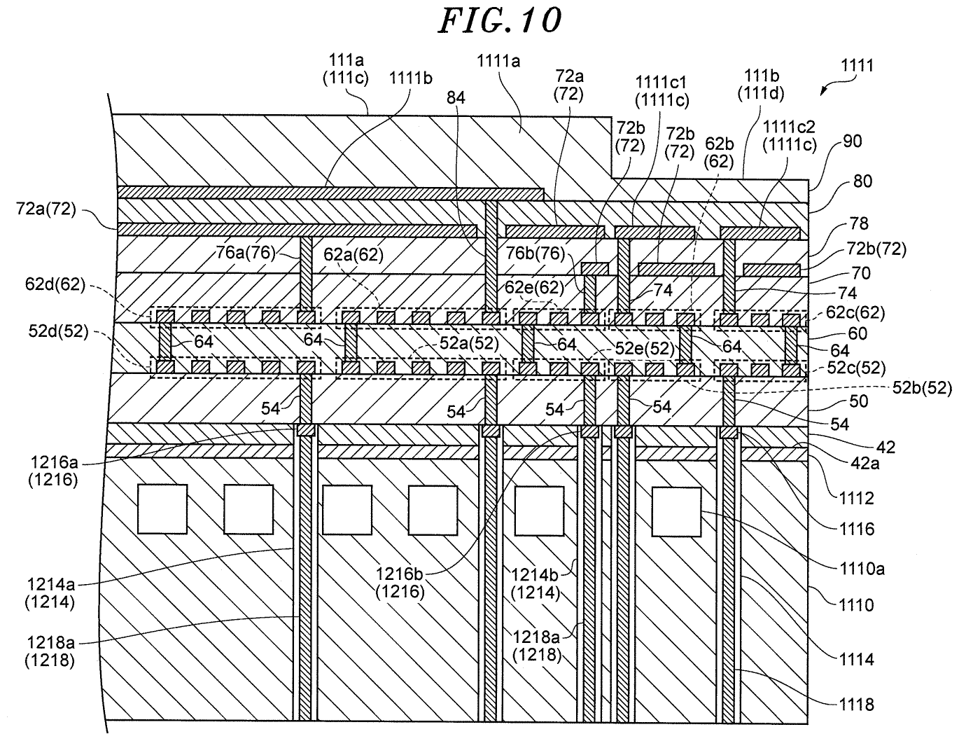

FIG. 9 shows another configuration example of the substrate support 11. In the example shown in FIG. 9, the substrate support 11 includes a bias electrode 72, plugs 76, a dielectric layer 78, an electrode 1216, and a power supply line 1218, in addition to the components of the substrate support 11 shown in FIG. 3.

The dielectric layer 78 is disposed between the dielectric layer 70 and the dielectric layer 80. The dielectric layer 78 may be integrally formed with the dielectric layer 70 and/or the dielectric layer 80. In other words, in FIG. 9, lines indicating boundaries between adjacent dielectric layers are illustrated for convenience of explanation. In other words, in FIG. 9, each dielectric layer may represent a region in the ceramic member 1111a. For example, physical boundaries may or may not exist between adjacent dielectric layers. Further, adjacent dielectric layers may contain the same dielectric material, or may contain different dielectric materials.

The bias electrode 72 has a bias electrode 72a and/or a bias electrode 72b. A bias RF signal and/or a bias DC signal is supplied to the bias electrodes 72a and 72b. The bias electrode 72a is disposed below the central region 111a. The bias electrode 72b is disposed below the annular region 111b.

The bias electrodes 72a and 72b are electrically connected to the power supply 30. The RF power supply 31 may provide a bias RF signal to the bias electrode 72a and/or the bias electrode 72b. The DC power supply 32 may supply a bias DC signal to the bias electrode 72a and/or the bias electrode 72b.

The bias electrode 72a may be disposed on the dielectric layer 78 in the ceramic member 1111a. In other words, the bias electrode 72a can be disposed on the same layer as the electrostatic electrode 1111c. The bias electrode 72a may be disposed on the dielectric layer 70. In a plan view of the substrate supporting portion 11, the bias electrode 72a can be disposed to surround the plug 84. Further, one ends of plugs 76a are connected to the bias electrode 72a.

The bias electrode 72b may be disposed on the dielectric layer 70 in the ceramic member 1111a. In other words, the bias electrode 72b may be disposed in the dielectric layer 78. In a plan view of the substrate supporting portion 11, the bias electrode 72b can be disposed to surround the plug 74. One end of a plug 76b is connected to the bias electrode 72b.

Further, two or more through-holes 1214 are formed in the base 1110. The two or more through-holes 1214 include one or more through-holes 1214a and one or more through-holes 1214b. The through-holes 1214 may have a structure similar to that of the through-holes 1114. Power supply lines 1218a are disposed in the through-holes 1214a. One ends of the power supply lines 1218a are electrically connected to the bias electrode 72a through electrodes 1216a disposed at the end portions of the through-holes 1214a. The other ends of the power supply lines 1218a are electrically connected to the DC power supply 32. Further, power supply lines 1218b are disposed in the through-holes 1214b. One ends of the power supply lines 1218b are electrically connected to the bias electrode 72b through electrodes 1216b disposed at the end portions of the through-holes 1214b. The other ends of the power supply lines 1218b are electrically connected to the DC power supply 32.

The bias electrode 72a can control the potential of the substrate W disposed in the central region 111a. The corresponding potential may be the potential of the substrate W with respect to the plasma processing space 10s. Further, the bias electrode 72b can control the potential of the ring assembly 112 disposed in the annular region 111b. The corresponding potential may be the potential of the ring assembly 112 with respect to the plasma processing space 10s. Further, the power supply 30 may supply the same bias signal or different bias signals to both the bias electrode 72a and the bias electrode 72b. Only one of the bias electrode 72a and the bias electrode 72b may be disposed at the substrate support 11.

<Still Another Configuration Example of Substrate Support 11>

FIG. 10 shows still another configuration example of the substrate support 11. In the example shown in FIG. 10, the substrate support 11 includes the filter elements 52 and 62 disposed between the bias electrode 72 and the RF power supply 31 or the DC power supply 32, in addition to the components of the substrate support 11 shown in FIG. 9. In other words, a bias RF signal or a bias DC signal can be applied to the bias electrode 72. For example, the substrate support 11 includes filter elements 52d, 52e, 62d and 62e. The filter elements 52d and 62d are examples of the first filter element. The filter elements 52e and 62e are examples of the second filter element. The bias electrode 72a is an example of the first electrode. The bias electrode 72b is an example of the second electrode.

The filter elements 52d and 52e may have the same configuration as those of the filter elements 52a to 52c. The filter elements 52d and 52e may be formed together with the filter elements 52a to 52c. The filter elements 52d and 52e may be disposed on the same layer as the filter elements 52a to 52c. The filter elements 62d and 62e may have the same configuration as those of the filter elements 62a to 62c. The filter elements 62d and 62e may be formed together with the filter elements 62a to 62c. The filter elements 62d and 62e may be disposed on the same layer as the filter elements 62a to 62c.

The bias electrode 72a is electrically connected to the RF power supply 31 or the DC power supply 32 through the power supply lines 1218a. In this example, one ends of the plugs 54 are connected to the electrodes 1216a, and the other ends of the plugs 54 are connected to the filter elements 52d. One ends of the plugs 64 are connected to the filter elements 52d, and the other ends of the plugs 64 are connected to the filter elements 62d. One ends of the plugs 76a are connected to the filter elements 62d, and the other ends of the plugs 76a are connected to the bias electrode 72a.

The bias electrode 72b is electrically connected to the RF power supply 31 or the DC power supply 32 through the power supply lines 1218b. In this example, one ends of the plugs 54 are connected to the electrodes 1216b, and the other ends of the plugs 54 are connected to the filter elements 52e. One ends of the plugs 64 are connected to the filter elements 52e, and the other ends of the plugs 64 are connected to the filter elements 62e. One ends of the plugs 76b are connected to the filter elements 62e, and the other ends of the plugs 76b are connected to the bias electrode 72b.

In accordance with the above embodiments, the filter element is disposed in the electrostatic chuck, that is, at a position close to the electrostatic chuck electrode. Accordingly, even if RF components are generated in the electrostatic chuck electrode by the source RF signal and/or the bias RF signal, the corresponding RF components can be attenuated in the electrostatic chuck. Hence, the loss of the RF power of the source RF signal and/or the bias RF signal can be reduced. Further, since the leakage of the corresponding RF components from the electrostatic chuck electrode to the outside of the electrostatic chuck can be reduced, it is possible to reduce the influence on the DC power supply electrically connected to the electrostatic chuck electrode.

In accordance with the above embodiments, the filter element is disposed relatively close to the temperature control module for controlling the temperature of the electrostatic chuck. Accordingly, even if the RF signal passes through the filter element, overheating of the filter element can be suppressed.

The present disclosure may include the following configuration, for example.

(Additional Statement 1)

A plasma processing apparatus comprising:

a plasma processing chamber;

a substrate support disposed in the plasma processing chamber, the substrate support including: a dielectric member having a substrate supporting surface; a first filter element disposed in the dielectric member, the first filter element having a first terminal and a second terminal; and a first electrode disposed in the dielectric member, the first electrode being electrically connected to the first terminal;

an RF generator coupled to the plasma processing chamber and configured to generate an RF signal; and

a first DC generator electrically connected to the second terminal and configured to generate a DC signal.

(Additional Statement 2)

The plasma processing apparatus of additional statement 1, wherein the first electrode includes an electrostatic chuck electrode.

(Additional Statement 3)

The plasma processing apparatus of additional statement 1 or 2, wherein the first electrode includes a bias electrode.

(Additional Statement 4)

The plasma processing apparatus of additional statement 1, wherein the first filter element is a low pass filter.

(Additional Statement 5)

The plasma processing apparatus of any one of additional statements 1 to 4, wherein the first filter element includes a first resistance element.

(Additional Statement 6)

The plasma processing apparatus of additional statement 5, wherein the first resistance element is disposed to be perpendicular to the substrate supporting surface.

(Additional Statement 7)

The plasma processing apparatus of additional statement 5 or 6, wherein the first resistance element is disposed to be parallel to the substrate supporting surface.

(Additional Statement 8)

The plasma processing apparatus of additional statement 7, wherein the first electrode is disposed to be parallel to the substrate supporting surface,

the first resistance element is disposed below the first electrode to be parallel to the first electrode, and

the first resistance element has the first terminal and the second terminal.

(Additional Statement 9)

The plasma processing apparatus of additional statement 8, wherein the first resistance element has a plurality of resistance wirings electrically connected each other in parallel between the first terminal and the second terminal.

(Additional Statement 10)

The plasma processing apparatus of any one of additional statements 7 to 9, wherein the first resistance element has a curved/bent line pattern in a plan view of the substrate supporting surface.

(Additional Statement 11)

The plasma processing apparatus of any one of additional statements 8 to 10, wherein the first filter element includes a second resistance element,

the second resistance element is disposed below the first resistance element to be parallel to the first resistance element,

the second resistance element has a third terminal and a fourth terminal,

the third terminal is electrically connected to the first electrode through the second terminal, and

the fourth terminal is electrically connected to the first DC generator.

(Additional Statement 12)

The plasma processing apparatus of any one of additional statements 1 to 4, wherein the first filter element includes a first inductor element.

(Additional Statement 13)

The plasma processing apparatus of additional statement 12, wherein the first inductor element is disposed to be parallel to the substrate supporting surface.

(Additional Statement 14)

The plasma processing apparatus of additional statement 13, wherein the first electrode is disposed to be parallel to the substrate supporting surface,

the first inductor element is disposed below the first electrode to be parallel to the first electrode, and

the first inductor element has the first terminal and the second terminal.

(Additional Statement 15)

The plasma processing apparatus of additional statement 13 or 14, wherein the first inductor element has a spiral line pattern in a plan view of the substrate supporting surface.

(Additional Statement 16)

The plasma processing apparatus of additional statement 14 or 15, wherein the first filter element includes a second inductor element,

the second inductor element is disposed below the first inductor element to be parallel to the first inductor element,

the second inductor element has a third terminal and a fourth terminal,

the third terminal is electrically connected to the first electrode through the second terminal, and

the fourth terminal is electrically connected to the first DC generator.

(Additional Statement 17)

The plasma processing apparatus of any one of additional statements 1 to 16, further comprising:

a second DC generator configured to generate a DC signal,

wherein the dielectric member has a ring supporting surface around the substrate supporting surface,

the substrate support includes:

a second filter element disposed in the dielectric member and having a fifth terminal and a sixth terminal; and

a second electrode disposed in the dielectric member and electrically connected to the fifth terminal, and

the second DC generator is electrically connected to the sixth terminal.

(Additional Statement 18)

The plasma processing apparatus of any one of additional statements 1 to 17, further comprising:

an RF electrode electrically connected to the RF generator,

wherein the RF electrode includes a metal member, and

the metal member is bonded to the dielectric member.

(Additional Statement 19)

An electrode chuck manufacturing method comprising: preparing a first dielectric layer having a first surface and a second surface opposite to the first surface;

forming an electrode on the first surface;

forming a plug in the first dielectric layer to penetrate therethrough, one end of the plug being connected to the electrode on the first surface and the other end of the plug being exposed on the second surface;

preparing a second dielectric layer having a third surface and a fourth surface opposite to the third surface;

forming a filter element on the third surface; and

connecting a part of the filter element and the other end of the plug by bonding the second surface of the first dielectric layer and the third surface of the second dielectric layer.

The above embodiments have been described for purposes of illustration, and various modifications can be made without departing from the scope and spirit of the present disclosure.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A plasma processing apparatus comprising:
a plasma processing chamber;
a substrate support disposed in the plasma processing chamber, the substrate support including:
a dielectric member having a substrate supporting surface;
a first filter element disposed in the dielectric member, the first filter element having a first terminal and a second terminal; and
a first electrode disposed in the dielectric member, the first electrode being electrically connected to the first terminal;
an RF generator coupled to the plasma processing chamber and configured to generate an RF signal; and
a first DC generator electrically connected to the second terminal and configured to generate a DC signal.

2. The plasma processing apparatus of claim 1, wherein the first electrode includes an electrostatic chuck electrode.

3. The plasma processing apparatus of claim 1, wherein the first electrode includes a bias electrode.

4. The plasma processing apparatus of claim 1, wherein the first filter element is a low pass filter.

5. The plasma processing apparatus of claim 1, wherein the first filter element includes a first resistance element.

6. The plasma processing apparatus of claim 5, wherein the first resistance element is disposed to be perpendicular to the substrate supporting surface.

7. The plasma processing apparatus of claim 5, wherein the first resistance element is disposed to be parallel to the substrate supporting surface.

8. The plasma processing apparatus of claim 7, wherein the first electrode is disposed to be parallel to the substrate supporting surface,
the first resistance element is disposed below the first electrode to be parallel to the first electrode, and
the first resistance element has the first terminal and the second terminal.

9. The plasma processing apparatus of claim 8, wherein the first resistance element has a plurality of resistance wirings electrically connected each other in parallel between the first terminal and the second terminal.

10. The plasma processing apparatus of claim 7, wherein the first resistance element has a curved/bent line pattern in a plan view of the substrate supporting surface.

11. The plasma processing apparatus of claim 8, wherein the first filter element includes a second resistance element,
the second resistance element is disposed below the first resistance element to be parallel to the first resistance element,
the second resistance element has a third terminal and a fourth terminal,
the third terminal is electrically connected to the first electrode through the second terminal, and
the fourth terminal is electrically connected to the first DC generator.

12. The plasma processing apparatus of claim 1, wherein the first filter element includes a first inductor element.

13. The plasma processing apparatus of claim 12, wherein the first inductor element is disposed to be parallel to the substrate supporting surface.

14. The plasma processing apparatus of claim 13, wherein the first electrode is disposed to be parallel to the substrate supporting surface,
the first inductor element is disposed below the first electrode to be parallel to the first electrode, and
the first inductor element has the first terminal and the second terminal.

15. The plasma processing apparatus of claim 13, wherein the first inductor element has a spiral line pattern in a plan view of the substrate supporting surface.

16. The plasma processing apparatus of claim 14, wherein the first filter element includes a second inductor element,
the second inductor element is disposed below the first inductor element to be parallel to the first inductor element,
the second inductor element has a third terminal and a fourth terminal,
the third terminal is electrically connected to the first electrode through the second terminal, and
the fourth terminal is electrically connected to the first DC generator.

17. The plasma processing apparatus of claim 1, further comprising:
a second DC generator configured to generate a DC signal,
wherein the dielectric member has a ring supporting surface around the substrate supporting surface,
the substrate support includes:
a second filter element disposed in the dielectric member and having a fifth terminal and a sixth terminal; and
a second electrode disposed in the dielectric member and electrically connected to the fifth terminal, and
the second DC generator is electrically connected to the sixth terminal.

18. The plasma processing apparatus of claim 1, further comprising:
an RF electrode electrically connected to the RF generator,
wherein the RF electrode includes a metal member, and
the metal member is bonded to the dielectric member.

19. An electrode chuck manufacturing method comprising:
preparing a first dielectric layer having a first surface and a second surface opposite to the first surface;
forming an electrode on the first surface;
forming a plug in the first dielectric layer to penetrate therethrough, one end of the plug being connected to the electrode on the first surface and the other end of the plug being exposed on the second surface;
preparing a second dielectric layer having a third surface and a fourth surface opposite to the third surface;
forming a filter element on the third surface; and
connecting a part of the filter element and the other end of the plug by bonding the second surface of the first dielectric layer and the third surface of the second dielectric layer.
